(19) United States
(12) Patent Application Publication
(10) Pub. No.: US 2025/0266267 A1
(43) Pub. Date: Aug. 21, 2025

(54) PROCESSING CHAMBER PURGE PLATE WITH SHROUD, AND PEDESTAL SHIELD SYSTEM

(71) Applicant: Lam Research Corporation, Fremont, CA (US)

(72) Inventors: Hans Peter NYGREN, Newark, CA (US); Eashan Raju DHAWADE, Nagpur (IN); Vinayakaraddy GULABAL, Yadgir (IN); Andrew Paul EIB, Campbell, CA (US); Ravi VELLANKI, San Jose, CA (US)

(21) Appl. No.: 18/857,602

(22) PCT Filed: Apr. 19, 2023
(86) PCT No.: PCT/US2023/019120

§ 371 Date: Oct. 17, 2024

Related U.S. Application Data
(60) Provisional application No. 63/364,011, filed on May 2, 2022.
(60) Provisional application No. 63/368,143, filed on Jul. 11, 2022.

(51) Int. Cl. H01L 21/67; H01J 37/32

(52) U.S. Cl. CPC H01L 21/67017; H01J 37/32724; H01J 37/32834; H01J 37/32899; H01J 2237/002

(57) ABSTRACT

Examples are disclosed that relate to a purge plate comprising a shroud. The shroud helps to avoid crosstalk between stations in a multi-station processing chamber. One example provides a processing tool comprising a processing chamber comprising a plurality of stations. The processing tool also comprises a purge plate comprising a chamber-facing surface. The purge plate further comprises a plurality of cutouts configured to accommodate process gas outlets of the plurality of stations. The purge plate further comprises a shroud arranged around at least a portion of a perimeter of a first cutout of a plurality of cutout. The shroud extends away from the chamber-facing surface. The purge plate further comprises a plurality of purge gas holes formed in the chamber-facing surface and the shroud.

### BACKGROUND

Semiconductor device fabrication processes may involve many steps of material deposition, patterning, and removal to form integrated circuits on substrates. Various methods can be used to selectively deposit materials onto a substrate. One example is chemical vapor deposition. Chemical vapor deposition processes involve flowing one or more precursor gases over a substrate within a processing chamber. Conditions in the chamber are controlled to cause the precursor gases to react and/or decompose on the substrate surface, thereby forming a film.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to a purge plate comprising a shroud. The shroud helps to avoid crosstalk between stations in a multi-station processing chamber. One example provides a processing tool comprising a processing chamber comprising a plurality of stations. The processing tool also comprises a purge plate comprising a chamber-facing surface. The purge plate further comprises a plurality of cutouts configured to accommodate process gas outlets of the plurality of stations. The purge plate further comprises a shroud arranged around at least a portion of a perimeter of a first cutout of the plurality of cutouts. The shroud extends away from the chamber-facing surface. The purge plate further comprises a plurality of purge gas holes formed in the chamber-facing surface and the shroud.

In some such examples, the shroud is a first shroud, and the processing tool comprises a second shroud arranged at least partially around the perimeter of a second cutout of the plurality of cutouts.

In some such examples, the plurality of purge gas holes alternatively or additionally comprises a pattern, and wherein the pattern is interrupted at an edge of the shroud.

In some such examples, the shroud alternatively or additionally extends away from the chamber-facing surface a distance within a range of between 0.10 inches and 0.25 inches.

In some such examples, the shroud alternatively or additionally is configured to accommodate one or more tabs of a transfer ring.

In some such examples, the processing chamber alternatively or additionally comprises four stations.

In some such examples, the processing tool further comprises a pedestal located at a station of the plurality of stations, a pedestal support that supports the pedestal above a bottom surface of the processing chamber, and a pedestal shield system comprising a side shield disposed around the pedestal support, a bottom shield that supports the side shield, the bottom shield comprising a plurality of adjustors configured to adjust one or more of a side shield tilt and a side shield height, the bottom shield further comprising one or more openings, and a radiation shield configured to absorb heat radiated from the pedestal and transfer the heat for removal from the processing chamber, the radiation shield comprising one or more foot pads that extend through the one or more openings of the bottom shield. Alternatively or additionally, in some such examples, the side shield is disposed around the pedestal, and the processing tool further comprises a purge gas outlet to flow purge gas into a space at least partially enclosed by the side shield. Alternatively or additionally, in some such examples, the processing tool further comprises a plurality of lift pins supported by the bottom shield, and wherein the plurality of adjustors of the bottom shield are further configured to adjust one or more of lift pin height and lift pin angle relative to pedestal angle, wherein the radiation shield comprises a plurality of cutouts configured to accommodate the plurality of lift pins.

In some such examples, the processing chamber alternatively or additionally comprises a chemical vapor deposition tool.

Another example provides a purge plate for a processing chamber in a processing tool. The purge plate comprises a chamber-facing surface. The purge plate further comprises a cutout configured to accommodate a corresponding process gas outlet of the processing tool. The purge plate further comprises a shroud arranged around at least a portion of a perimeter of the cutout. The shroud extends from the chamber-facing surface. The purge plate further comprises a plurality of purge gas holes formed in the chamber-facing surface and the shroud.

In some such examples, the purge plate comprises a unitary body.

In some such examples, the purge plate alternatively or additionally is formed from aluminum.

In some such examples, the shroud is a first shroud, and the purge plate comprises a second shroud arranged around a second cutout.

In some such examples, the plurality of purge gas holes alternatively or additionally comprises a pattern, and the pattern being interrupted at an edge of the shroud.

In some such examples, the shroud alternatively or additionally extends away from the chamber-facing surface a distance within a range of between 0.10 inches and 0.25 inches.

In some such examples, the purge plate alternatively or additionally comprises a second, third, and fourth cutout.

In some such examples, the shroud alternatively or additionally comprises one or more notches configured to accommodate one or more tabs of a transfer ring.

In some such examples, the purge plate alternatively or additionally is configured for a deposition chamber of a chemical vapor deposition tool.

Another example provides a method of processing a plurality of substrates within a processing chamber of a processing tool. The processing chamber comprises a plurality of stations and a corresponding plurality of process gas outlets. The processing chamber further comprises a purge plate. The purge plate comprises a plurality of cutouts configured to accommodate the plurality of process gas outlets. The method comprises flowing a first precursor gas over a first substrate at a first station. The method further comprises flowing a second precursor gas over a second substrate at a second station. The method further comprises flowing a purge gas through purge holes formed through a chamber-facing surface of the purge plate. The method further comprises flowing the purge gas through purge holes formed through a shroud of the purge plate. The shroud is arranged around at least a portion of a perimeter of a first cutout of the plurality of cutouts.

In some such examples, the shroud is a first shroud, and the method further comprises flowing the purge gas through purge holes formed in a second shroud of the purge plate. The second shroud arranged at least partially around a portion of a second cutout of the plurality of cutouts.

In some such examples, the method of processing the plurality of substrates alternatively or additionally further comprises an additional method, the additional method comprising performing a chemical vapor deposition process.

In some such examples, the method alternatively or additionally further comprises, after flowing the first precursor gas, transferring the first substrate to the second station, and after flowing the second precursor gas, transferring the second substrate to a third station.

Examples also are disclosed that relate to a pedestal shield system for protecting a pedestal system of a substrate processing tool. One example provides a substrate processing tool comprising a processing chamber, a substrate heater, and a pedestal system disposed within the processing chamber. The pedestal system comprises a pedestal and a pedestal support configured to support the pedestal above a bottom surface of the processing chamber. The substrate processing tool further comprises a pedestal shield system. The pedestal shield system comprises a side shield disposed around the pedestal support. The pedestal shield system further comprises a bottom shield that supports the side shield, the bottom shield comprising a plurality of adjustors configured to adjust one or more of a side shield tilt and a side shield height, the bottom shield further comprising one or more openings. The pedestal shield system further comprises a radiation shield configured to absorb heat radiated from the pedestal and transfer the heat for removal from the processing chamber, the radiation shield comprising one or more foot pads that extend through the one or more openings of the bottom shield.

In some such examples, the side shield is disposed around the pedestal.

In some such examples, the substrate processing tool additionally or alternatively further comprises a purge gas outlet to flow purge gas into a space at least partially enclosed by the side shield.

In some such examples, the substrate processing tool additionally or alternatively further comprises a plurality of lift pins supported by the bottom shield.

In some such examples, the plurality of adjustors of the bottom shield additionally or alternatively are further configured to adjust one or more of lift pin height and lift pin angle relative to pedestal angle.

In some such examples, the radiation shield additionally or alternatively comprises a plurality of cutouts configured to accommodate the plurality of lift pins.

In some such examples, the substrate processing tool additionally or alternatively comprises a chemical vapor deposition tool.

In some such examples, the side shield and bottom shield additionally or alternatively are integrated.

In some such examples, the side shield additionally or alternatively comprises aluminum.

Another example provides a pedestal shield system for a substrate processing tool. The pedestal shield system comprises a side shield configured to be disposed around a pedestal support of a pedestal system of the substrate processing tool. The pedestal shield system further comprises a bottom shield configured to support the side shield. The bottom shield comprises a plurality of adjustors configured to adjust one or more of a side shield tilt and a side shield height. The bottom shield further comprises one or more openings. The pedestal shield system further comprises a radiation shield configured to absorb heat radiated from the pedestal support and the pedestal. The radiation shield comprises one or more foot pads configured to extend through the one or more openings of the bottom shield.

In some such examples, the bottom shield is configured to support a plurality of lift pins.

In some such examples, the adjustors of the bottom shield additionally or alternatively are further configured to adjust one or more of lift pin height and lift pin angle relative to pedestal angle.

In some such examples, the plurality of lift pins additionally or alternatively comprises three or more lift pins and the adjustors of the bottom shield are further configured to adjust a lift pin planarity relative to a pedestal surface.

In some such examples, the radiation shield additionally or alternatively further comprises a plurality of cutouts configured to accommodate the plurality of lift pins.

In some such examples, the side shield and bottom shield additionally or alternatively are integrated.

In some such examples, the side shield additionally or alternatively comprises aluminum.

Another examples provides a method of adjusting a processing tool comprising a processing chemical outlet, a pedestal system, and a pedestal shield system. The pedestal system comprises a pedestal and a pedestal support. The pedestal shield system comprises a bottom shield, a side shield disposed around the pedestal and supported by the bottom shield, and a radiation shield comprising one or more foot pads that extend through one or more openings in the bottom shield. The method comprises adjusting a tilt angle of the pedestal relative to the processing chemical outlet. The method further comprises adjusting one or more adjustors on the bottom shield to adjust a position of the side shield relative to the pedestal.

In some such examples, the method further comprises applying a vacuum to a processing chamber of the processing tool before adjusting the tilt angle of the pedestal.

In some such examples, the method additionally or alternatively further comprises introducing a purge gas into a space that is at least partially surrounded by the side shield.

In some such examples, adjusting the one or more adjustors additionally or alternatively comprises adjusting one or more of a screw, a cam, a rack and pinion gear, a level, a piston, or a wedge.

### BRIEF DESCRIPTION OF THE DRAWINGS

FIG. 1 shows an example processing tool comprising a plurality of stations within a processing chamber.

FIG. 2 shows a side schematic view of an example station comprising a purge plate with a shroud.

FIG. 3 schematically shows an exploded view of selected components of an example four-station processing chamber.

FIG. 4 schematically shows a bottom view of an example purge plate comprising a shroud positioned around a portion of a cutout.

FIG. 5 schematically shows a bottom view of an example purge plate comprising a plurality of shrouds.

FIG. 6 schematically shows a bottom view of an example purge plate comprising a shroud including notches to accommodate a transfer ring.

FIG. 7 schematically shows an example pattern of purge holes formed in a purge plate.

FIG. 8 shows a flow diagram of an example method for processing substrates in a multi-station processing chamber.

FIG. 9 schematically shows an example processing tool comprising a plurality of pedestal systems and a corresponding plurality of pedestal shield systems located within a processing chamber.

FIG. 10 shows a schematic view of a cross-section of an example a pedestal shield system within a processing chamber.

FIGS. 11A-11C schematically show adjustment of a pedestal and pedestal shield system relative to a processing chemical outlet.

FIG. 12 shows an example side shield configured for use in a pedestal shield system.

FIG. 13 shows an example bottom shield configured for use in a pedestal shield system.

FIG. 14 shows an example integrated side shield and bottom shield.

FIG. 15 shows a top view of an example radiation shield configured for use in a pedestal shield system.

FIG. 16 shows a bottom view of the radiation shield of FIG. 15.

FIG. 17 shows a flow diagram of an example method for adjusting a processing tool comprising a pedestal system and a pedestal shield system.

FIG. 18 shows a block diagram of an example computing system.

### DETAILED DESCRIPTION

The term “adjustor” generally represents a component of a bottom shield that is capable of adjusting a height of a location of the bottom shield relative to an underlying surface, such as a bottom surface of a processing chamber. Example adjustors may include one or more of a screw, a cam, a rack and pinion gear, a lever, a piston, or a wedge.

The term “atomic layer deposition” generally represents a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD) and thermal ALD (TALD). PEALD utilizes a plasma of a reactive gas to facilitate a chemical conversion of a precursor adsorbed to a substrate to a film on the substrate. TALD uses heat to facilitate a chemical conversion of a precursor adsorbed to a substrate to a film on the substrate.

The term “bottom shield” generally represents a component in a pedestal shield system that supports a side shield and/or one or more lift pins.

The term “bottom surface of a processing chamber” generally represents a surface which defines a lower interior boundary of a processing chamber.

The term “chemical vapor deposition” generally represents a process for depositing a film on a substrate by flowing one or more precursor gases over a substrate under conditions which cause the precursor gas(es) to react to form a film on the substrate surface.

The term “chemical vapor deposition tool” generally represents a processing tool configured to perform chemical vapor deposition.

The term “cutout” generally represents a feature in a purge plate that is configured to accommodate a process gas outlet. A cutout may be formed in an edge of a purge plate. A cutout also may be formed in an interior of a purge plate.

The term “foot pad” generally represents a structural feature of a radiation shield that is configured to extend downwardly through an opening in a bottom shield.

The term “indexing plate” generally represents a substrate transfer mechanism in a multi-station processing tool that can rotate substrates between stations.

The term “lift pin” generally represents a structure configured to extend through a corresponding hole in a pedestal to support a substrate above a pedestal surface when a height of an upper end of the lift pin is elevated above a height of the pedestal surface.

The term “lift pin cutout” generally represents a structure in a radiation shield that is configured to accommodate one or more lift pins.

The term “lift pin height” generally represents a distance from a bottom surface of a processing chamber to an upper end of a lift pin.

The term “lift pin angle” generally represents an angle of a direction of a long axis of a lift pin relative to a direction of a long axis of a pedestal support.

The term “lift pin planarity” generally represents a degree of planarity between a plane defined by upper ends of three or more lift pins and a pedestal surface.

The term “lift pin hole” generally represents an opening in a pedestal to accommodate a lift pin.

The term “pedestal” generally represents a structure configured to support a substrate within a processing chamber. A pedestal may include any suitable structure for supporting and/or holding a substrate, such as a chuck.

The term “pedestal system” generally represents a system including a pedestal and a pedestal support.

The term “pedestal support” generally represents a support column configured to support a pedestal. In some examples, a pedestal support is configured to adjust a tilt angle of a pedestal relative to a processing chemical outlet.

The term “pedestal shield system” generally represents a system configured to at least partially protect a pedestal system from processing conditions in a processing chamber. A pedestal shield system may comprise a bottom shield, a side shield, and a radiation shield. The bottom shield and side shield may be integrated or separate in various examples.

The term “pedestal” generally represents a structure configured to support a substrate within a processing chamber. A pedestal may include any suitable structure for supporting and/or holding a substrate, such as a chuck.

The term “pedestal system” generally represents a system including a pedestal and a pedestal support.

The term “pedestal support” generally represents a support column configured to support a pedestal. In some examples, a pedestal support is configured to adjust a tilt angle of a pedestal relative to a processing chemical outlet.

The term “pedestal shield system” generally represents a system configured to at least partially protect a pedestal system from processing conditions in a processing chamber. A pedestal shield system may comprise a bottom shield, a side shield, and a radiation shield. The bottom shield and side shield may be integrated or separate in various examples.

The terms “process gas outlet” and “processing chemical outlet” generally represents an outlet configured to introduce a process chemical or process chemical mixture onto a substrate during a chemical process. Showerheads and nozzles are examples of process gas and process chemical outlets. The term “showerhead” generally represents a process chemical outlet comprising a plurality of holes distributed across an area.

The term “processing chamber” generally represents an enclosure in which chemical and/or physical processes are performed on substrates. Example chemical processes include chemical vapor deposition (CVD), atomic layer deposition (ALD), and dry etching processes.

The terms “processing tool” and “substrate processing tool” generally represents a machine including a processing chamber and other hardware configured to enable processing to be carried out in the processing chamber. The term “purge gas” generally represents any suitable gas, such as an inert gas, used to remove processing gases from at least a portion of a processing chamber. A purge gas may be used to isolate processing stations from one another in a multi-station processing tool.

The term “purge gas” generally represents any suitable gas, such as an inert gas, used to remove at least a portion of processing chemicals from a processing chamber. Example purge gases include nitrogen (N₂), argon (Ar), neon (Ne), and helium (He).

The term “purge gas outlet” generally represents an outlet through which a purge gas is introduced into a location in a processing chamber.

The term “purge plate” generally represents a structure defining at least a portion of a processing chamber enclosure, and that comprises holes through which a purge gas may flow into the processing chamber. The term “purge hole” may represent any hole in purge plate configured for purge gas flow. The term “chamber-facing surface” generally represents a surface of a purge plate that faces an interior of a processing chamber.

The term “radiation shield” generally represents a structure configured to absorb heat radiated from a pedestal system within a processing chamber and conduct the heat for removal from the processing chamber. A radiation shield comprises one or more foot pads to transfer heat to another structure in a processing chamber. In some examples, the foot pads may transfer heat to a bottom surface of the processing chamber.

The term “shim” generally represents a structure that can be placed between a lift pin and an underlying surface, such as a bottom shield.

The term “shroud” generally represents any structure which extends from a chamber-facing surface of a purge plate to inhibit migration of process gases from one process station toward one or more other process stations in a processing chamber.

The term “side shield” generally represents a structure disposed around a pedestal support and configured to help protect a pedestal system from processing chamber conditions. A side shield may be supported by and/or integrated with a bottom shield.

The term “station” generally represents a location in a processing tool at which a chemical and/or physical process is performed on a substrate.

The term “substrate” generally represents any object that can be processed at a station in a processing chamber of a processing tool.

The term “substrate heater” generally represents a heater configured to heat a substrate during processing. In some examples, a substrate heater may be incorporated into a pedestal.

The term “substrate holder” generally represents a structure configured for supporting a substrate and/or a transfer ring holding a substrate. Examples include pedestals and chucks.

The term “transfer ring” generally represents a structure configured to hold a substrate during transfer between processing stations.

The term “unitary body” generally represents a single-piece structure, without joints formed by welds, adhesives, or fasteners.

As mentioned above, the fabrication of integrated circuits on substrates involves many individual steps of material addition, patterning, modification, and removal. For example, chemical vapor deposition may be used to deposit films of a variety of compositions on a substrate surface. Chemical vapor deposition involves exposing a substrate to one or more reactive precursor gases under conditions that cause the precursor gas(es) to react and/or decompose on the substrate.

Chemical vapor deposition is generally performed in a processing chamber under a controlled gaseous environment. Some processing tools may comprise multiple stations located in a same processing chamber. Such a configuration allows multiple substrates to be processed in parallel. This may help to achieve higher throughput relative to a processing chamber with a single station.

Different stations within a processing chamber may perform different chemical processes in parallel. However, performing different chemical processes at different stations in parallel may pose a risk of migration of processing gases between process stations. Such migration of processing gases between process stations may be referred to as “crosstalk.” In some situations, crosstalk between stations may pose a risk of contaminating a film being grown.

To help prevent migration of processing gases between stations, a flow of a purge gas may be directed between stations. For example, a processing chamber may comprise a purge plate. The purge plate may comprise a plurality of holes configured to direct a flow a purge gas between stations. The purge gas flow isolates processing environments of the stations. The purge gas may flow from the purge plate toward chamber exhaust ports in a bottom portion of the processing chamber and be removed by a vacuum pumping system. In this manner, unreacted precursor gases and reaction products may be drawn with the flow of purge gas towards the exhaust ports.

However, some processing conditions may cause transient disruptions in a desired flow pattern of purge gas and process gases (reactants and/or products) toward an exhaust port. Accordingly, to provide further prevention against crosstalk in such conditions, examples are disclosed that relate to the use of a purge plate comprising one or more shrouds. Briefly, a purge plate of a processing chamber comprises a plurality of cutouts configured to accommodate a plurality of process gas outlets within the processing chamber. For at least one of the cutouts, a shroud is arranged around at least a portion of a perimeter of the cutout. The shroud extends from the chamber-facing surface of the purge plate into the processing chamber. The shroud thus helps to direct precursor gases and/or reaction products from the corresponding process gas outlet toward an exhaust port, and away from other processing stations. Further, the purge plate comprises a plurality of purge holes configured to direct a flow of purge gas between process stations. The use of a purge plate comprising purge holes and one or more shrouds as disclosed herein may help to reduce the risk of crosstalk between stations of the processing tool. While described herein in the context of a chemical vapor deposition tool, a purge plate comprising a shroud as disclosed herein may be used in any other suitable processing tool. Examples include atomic layer deposition tools, plasma etching tools, and atomic layer etching tools.

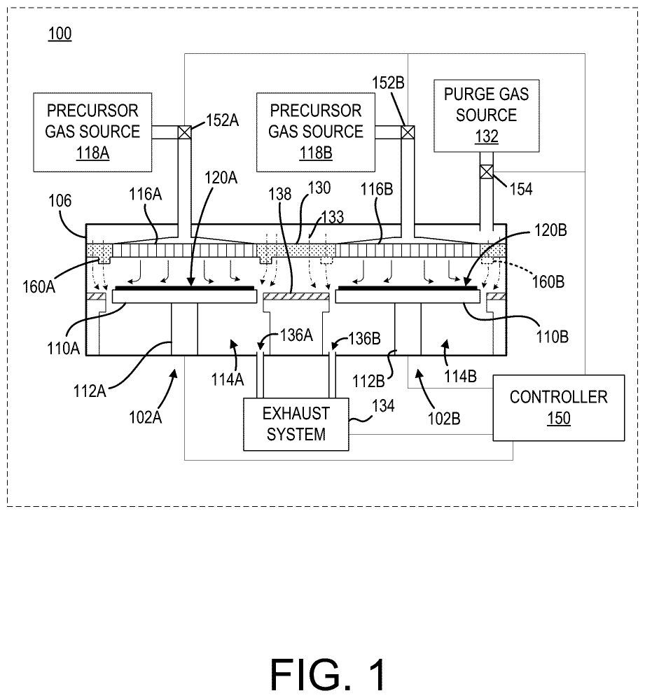

FIG. 1 shows a schematic view of an example processing tool 100 (e.g., a multi-station processing tool) that can be utilized to process multiple substrates in parallel. FIG. 1 illustrates a first station 102A and a second station 102B within a processing chamber 106. In some examples, processing tool 100 comprises a chemical vapor deposition tool and processing chamber 106 comprises a deposition chamber. First station 102A and second station 102B are configured to expose substrates to one or more precursor gases, e.g., as part of chemical vapor deposition. Processing tool 100 further may comprise additional stations not shown in FIG. 1. In some examples, processing tool 100 comprises four stations. However, any suitable number of stations may be used.

First station 102A comprises a first substrate holder 110A and a first substrate holder support 112A positioned within a first well 114A of processing chamber 106. First station 102A further comprises a first process gas outlet 116A in fluid connection with a first precursor gas source 118A. First precursor gas source 118A is configured to provide one or more precursor gases to first process gas outlet 116A. First substrate holder 110A supports a first substrate 120A during processing. In some examples, first substrate holder 110A may support a transfer ring holding first substrate 120A. First substrate holder support 112A may be configured to raise and lower first substrate holder 110A, for example, to adjust the gap between first substrate holder 110A and first process gas outlet 116A.

Similarly, second station 102B comprises a second substrate holder 110B and a second substrate holder support 112B positioned within a second well 114B. Second station 102B further comprises a second process gas outlet 116B in fluid connection with a second precursor gas source 118B. Second precursor gas source 118B is configured to provide one or more precursor gases to second process gas outlet 116B. Second substrate holder 110B supports second substrate 120B during processing at second station 102B. In some examples, second substrate holder 110B may support a transfer ring holding second substrate 120B. Second substrate holder support 112B may be configured to raise and lower second substrate holder 110B.

Processing chamber 106 further comprises a purge plate 130. Purge plate 130 comprises cutouts to accommodate first process gas outlet 116A and second process gas outlet 116B. Processing tool 100 further comprises a purge gas source 132 comprising a purge gas that can be directed into processing chamber 106 via purge gas holes (indicated by purge gas flow arrow 133 and similar arrows) formed in purge plate 130. In the depicted example, purge plate 130 comprises a top plate that forms a top boundary of processing chamber 106. In other examples, a purge plate may have any other suitable location and/or orientation in a processing chamber.

Processing chamber 106 may be evacuated via an exhaust system 134 comprising one or more exhaust ports 136A-B. In the depicted example, first station 102A comprises a first exhaust port 136A. Similarly, second station 102B comprises a second exhaust port 136B.

Processing chamber 106 further comprises an indexing plate 138 configured to transfer substrate between stations. Indexing plate 138 may be configured to lift substrates 120A-B from corresponding substrate holders 110A-B. In some examples, indexing plate may be configured to lift transfer rings holding substrates 120A-B. After lifting substrates 120A-B, indexing plate 138 rotates to advance substrates 120A-B to respective next stations.

Processing tool 100 further comprises a controller 150 configured to control processing tool 100 to perform process cycles. For example, controller 150 is controllably connected to valves 152A, 152B, and 154 to control process gas flows and purge gas flows during and between process cycles. Controller 150 is also controllably connected to exhaust system 134. Controller 150 may control valves 152A, 152B, 154 and exhaust system 134 to control pressure and gas composition inside processing chamber 106. Controller 150 also may control substrate holder supports 112A, 112B to raise and lower substrates. Controller 150 further may control indexing plate 138 to transfer substrates between stations. Controller 150 additionally may control other components not shown in FIG. 1, such as substrate holder heaters, gas line heaters, substrate transfer robots, load locks, and/or any other suitable components.

During substrate processing, controller 150 controls valve 152A to flow one or more precursor gases from first precursor gas source 118A over first substrate 120A at first station 102A. Likewise, controller 150 controls valve 152B to flow one or more precursor gases from second precursor gas source 118B over second substrate 120B at second station 102B.

As mentioned above, different precursor gases may be provided to first process gas outlet 116A and second process gas outlet 116B. Thus, to help prevent crosstalk, controller 150 controls valve 154 to flow purge gas through purge holes in purge plate 130. Purge plate 130 comprises a first shroud 160A positioned at least partially around the cutout that accommodates first process gas outlet 116A. First shroud 160A may help prevent crosstalk between first station 102A and second station 102B by directing flows of precursor gases and/or reaction products from first process gas outlet 116A towards first exhaust port 136A. This may help to maintain a desired gas flow pattern even when transient conditions disrupt an ordinary flow pattern. In some examples, purge plate 130 may comprise a plurality of shrouds for a corresponding plurality of stations. For example, as indicated at 160B, purge plate 130 may comprise a second shroud 160B positioned at least partially around the cutout that accommodates second process gas outlet 116B. In other examples, second shroud 160B may be omitted.

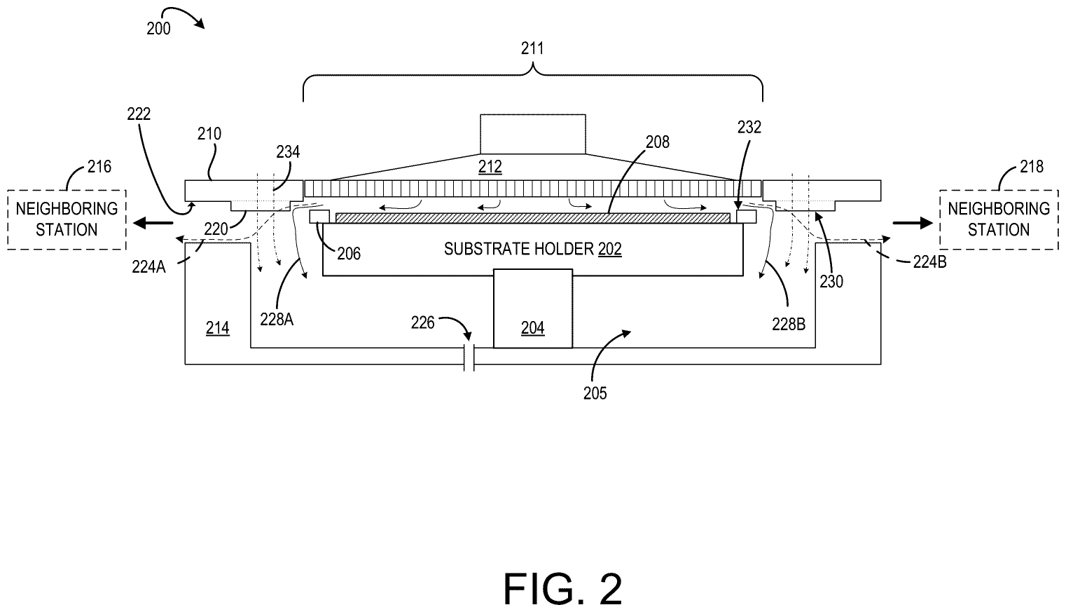

FIG. 2 schematically shows a side view of an example station 200 comprising a purge plate comprising a shroud. Station 200 may represent first station 102A and/or second station 102B in FIG. 1 in some examples. Station 200 comprises a substrate holder 202 and substrate holder support 204 positioned in a well 205. A transfer ring 206 is positioned around a substrate 208 on substrate holder 202. In other examples, a transfer ring may be omitted, as substrates may be transferred by robots that handle the substrates directly. Station 200 further comprises a purge plate 210 with a cutout 211 to accommodate a process gas outlet 212. Process gas outlet 212 is configured to distribute a precursor gas or precursor gas mixture over substrate 208. Station 200 further comprises walls 214 separating well 205 from a neighboring station (e.g., station 216 or station 218).

Purge plate 210 comprises a shroud 220 that extends from a chamber-facing surface 222 of purge plate 210 to help prevent crosstalk. In some examples, purge plate 210 comprises a unitary body that includes shroud 220. Such a purge plate may be machined, cast, or formed in any other suitable manner. In other examples, shroud 220 may be incorporated into purge plate 210 via a welded joint, fasteners, an adhesive, and/or other suitable connection. Purge plate 210 may comprise any suitable material. For example, purge plate 400 may be formed from a metal (e.g., aluminum or corrosion-resistant steel) or a ceramic. As discussed above, in the absence of shroud 220, there may be a risk of residual precursor gases and/or reaction products migrating toward other stations, as illustrated by arrows 224A and 224B. Instead, shroud 220 helps to directs the precursor gas towards an exhaust port 226 in well 205, as illustrated by arrows 228A and 228B.

In this example, purge gas holes are formed in shroud 220, as indicated by purge gas flow arrow 234 and similar arrows. While not shown in FIG. 2, purge gas also may flow through other regions of purge plate 210 via purge holes. Example purge hole arrangements are described in more detail below.

In some examples, shroud 220 may extend from chamber-facing surface 222 sufficiently far that, when substrate holder 202 and process gas outlet 212 are positioned for substrate processing, a lower surface 230 of shroud 220 is below an upper surface 232 of transfer ring 206. In other examples shroud 220 may be configured to extend from chamber-facing surface 222 a lesser distance. In some examples, shroud 220 extends out from chamber-facing surface 222 a distance within a range of between 0.10 inches and 0.25 inches. In other examples, a shroud may extend any other suitable distance from chamber-facing surface 222.

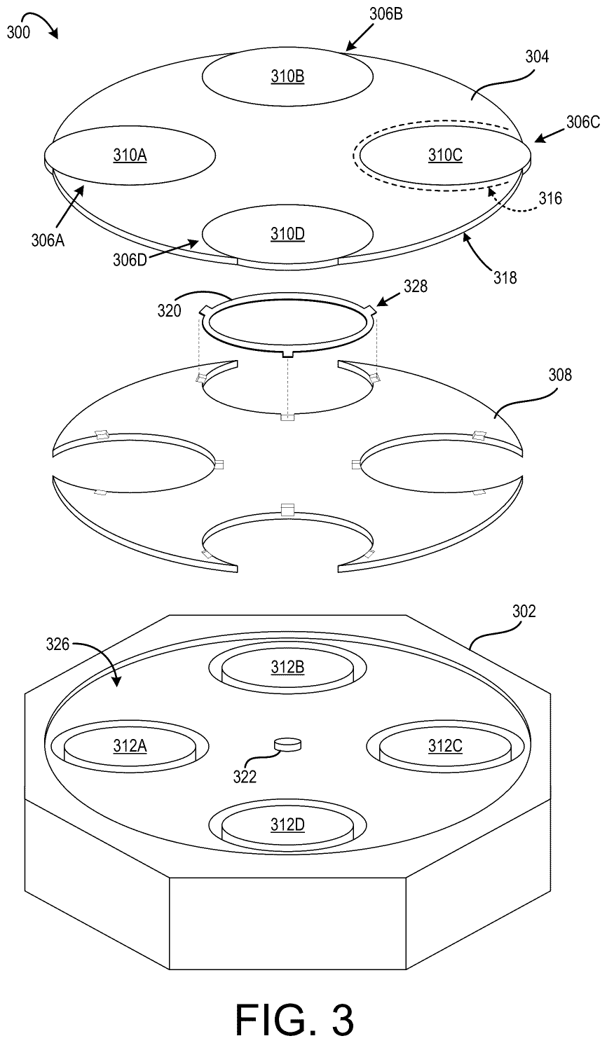

As mentioned above, a processing chamber may have any suitable number of stations. FIG. 3 shows an exploded view of example components 300 for a processing chamber that includes four process stations. The illustrated components include a chamber base 302, a purge plate 304 comprising cutouts 306A-D, an indexing plate 308, process gas outlets 310A-D, and substrate holders 312A-D.

Purge plate 304 is configured to define an upper boundary of a processing chamber. Purge plate 304 comprises a shroud 316 positioned on a chamber-facing surface 318. Shroud 316 is hidden from view in FIG. 3. However, the shroud position is indicated schematically by a dashed line on an opposite surface of purge plate 304. Shroud 316 is arranged around a perimeter of cutout 306C. Purge plate 304 further comprises purge holes formed in chamber-facing surface 318 and shroud 316 for flowing purge gas into the processing chamber. The purge holes are omitted from FIG. 3 for clarity, but are described in more detail below. While FIG. 3 illustrates a shroud positioned around one cutout, in other examples shrouds may be positioned around two or more cutouts.

In some examples, substrates are held by transfer rings, such as transfer ring 320. In such examples, indexing plate 308 is configured to move the corresponding transfer rings. During indexing, substrate holders 312A-D may be lowered, and/or indexing plate 308 may be raised via spindle 322, to lift the transfer rings from corresponding substrate holders. Indexing plate 308 may then rotate to advance the transfer rings and corresponding substrates. Then, indexing plate 308 may be lowered and/or substrate holders 312A-D may be raised to position the substrates on substrate holders 312A-D for a process cycle. Shroud 316 of purge plate 304 may be configured to accommodate transfer rings 320, including tabs 328, as described below.

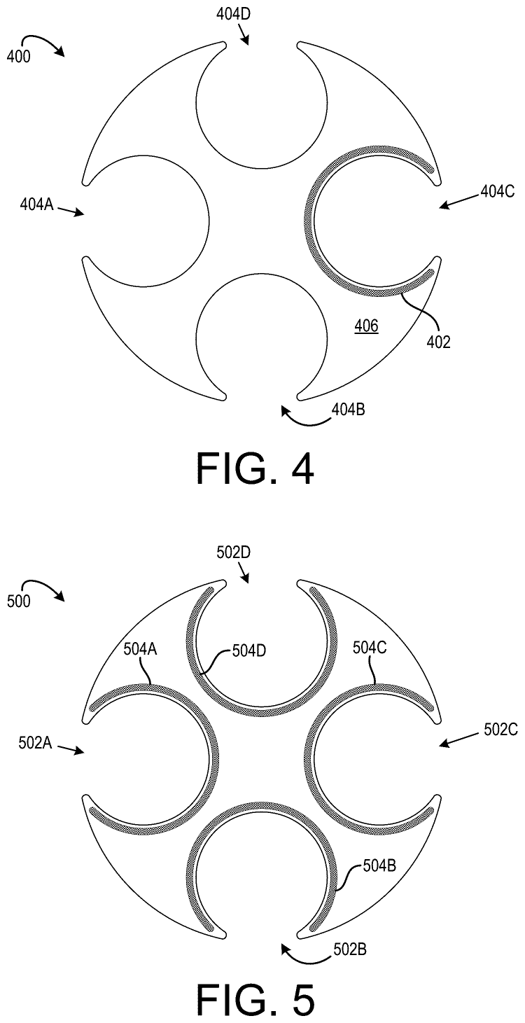

FIGS. 4-6 shows example purge plates which can be used in a four-station processing chamber to help prevent crosstalk between stations. First, FIG. 4 depicts a bottom view of an example purge plate 400 comprising a shroud 402. In some examples, shroud 402 can be a single shroud. Shroud 402 is located on a chamber-facing surface of purge plate 400. Purge plate 400 comprises a plurality of cutouts 404A-D. Each cutout can be configured to accommodate a respective process gas outlet. Shroud 402 is arranged around a portion the perimeter of cutout 404C. In some examples, purge plate 400 is configured for a deposition chamber of a chemical vapor deposition tool.

As mentioned above, purge plate 400 may comprise a unitary body. In such examples, purge plate 400 may be machined, cast, or otherwise formed as a single piece. In other examples, shroud 402 may comprise a separate piece from a planar portion 406 of purge plate 400. In such examples, shroud 402 may be coupled to the planar portion 406 of purge plate 400 in any suitable manner. Examples may include welding, one or more fasteners, and/or a suitable adhesive. Purge plate 400 may comprise any suitable material, such as aluminum, corrosion-resistant steel, or ceramic.

FIG. 5 depicts a bottom view of another example purge plate. Purge plate 500 comprises a plurality of cutouts 502A-D configured to accommodate a corresponding plurality of process gas outlets. Purge plate 500 further comprises shrouds 504A-D respectively arranged partially around cutouts 502A-D. In other examples, shrouds may be arranged around the perimeter of any suitable number of cutouts. In some examples, purge plate 500 is configured for a deposition chamber of a chemical vapor deposition tool. Purge plate 500 may comprise any suitable material, such as aluminum, corrosion-resistant steel, or ceramic.

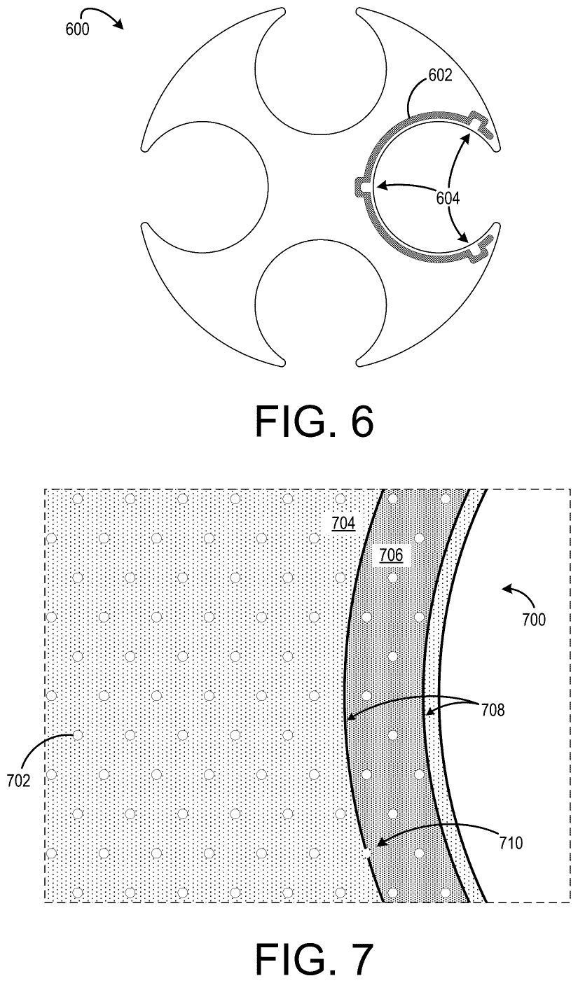

FIG. 6 shows another example purge plate 600. Purge plate 600 comprises a shroud 602 having notches 604 to accommodate a transfer ring. In the depicted example, shroud 602 comprises three notches 604 to accommodate corresponding tabs of a transfer ring. In other examples, a shroud may have a different number of notches to accommodate a different transfer ring configuration. In some examples, purge plate 600 is configured for a deposition chamber of a chemical vapor deposition tool. Purge plate 600 may comprise any suitable material, such as aluminum, corrosion-resistant steel, or ceramic.

As mentioned above, a purge plate may comprise purge holes through which a purge gas can flow to help maintain separate processing environments at different processing stations. FIG. 7 shows a magnified view of an example purge plate 700 comprising purge holes 702. Purge plate 700 may represent any of the example purge plates described herein. In the depicted example, purge holes 702 extend through both a planar portion 704 of purge plate 700 and through shroud 706. In some examples, purge holes 702 may be formed in a pattern which may help achieve a relatively uniform purge. In such examples, the pattern may be interrupted at edges 708 of shroud 706. For example, the pattern of purge holes 702 may place a purge hole at 710. As 710 is located at an edge 708, the purge hole is omitted at 710. Purge holes may be omitted at shroud edges for manufacturability and/or to avoid disrupting a desired purge flow pattern. While the example in FIG. 7 depicts a regular pattern of purge holes, any suitable regular or irregular arrangement of purge holes may be used. Purge holes 702 may be formed in any suitable manner. For example, purge holes 702 can be machined into purge plate 700.

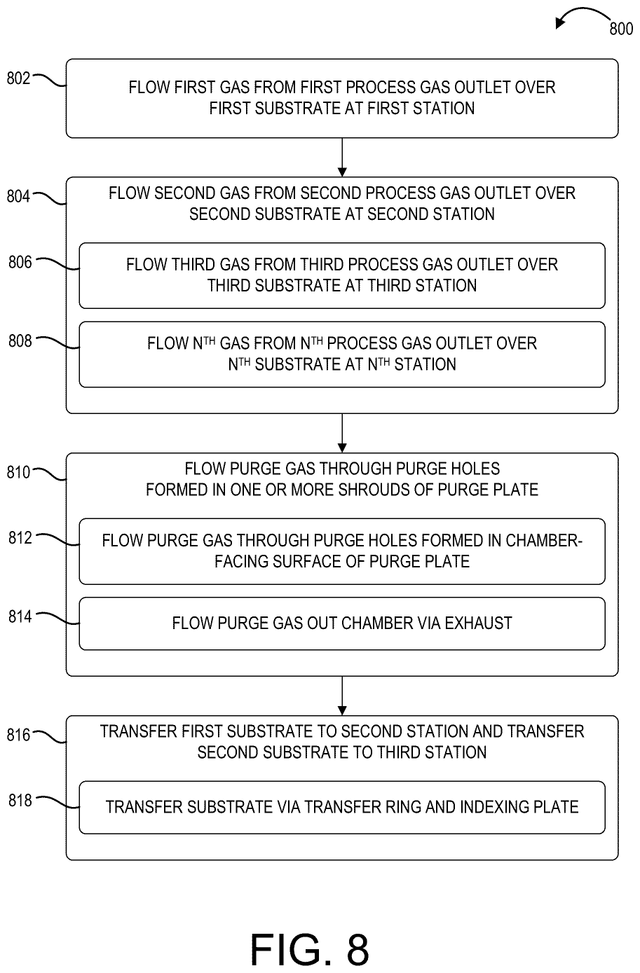

FIG. 8 shows a flow diagram for an example method 800 for processing multiple substrates within a single processing chamber, such as the example processing chambers described herein. Method 800 may represent a chemical vapor deposition process, or any other suitable process. Method 800 may be controlled by a controller of a processing tool, such as controller 150 of processing tool 100.

At 802, method 800 comprises flowing a first precursor gas or gas mixture from a first process gas outlet over a first substrate at a first station. At 804, method 800 further comprises flowing a second, different precursor gas or gas mixture from a second process gas outlet over a second substrate at a second station. Further, in some examples, at 806, method 800 comprises flowing a third precursor gas or gas mixture from a third process gas outlet over a third substrate at a third station. The third precursor gas or gas mixture may be the same as the first or the second gases or gas mixtures, or may be different. In some examples, the processing chamber may comprise additional stations. As such, in some examples, at 808, method 800 comprises flowing an N^{th} precursor gas from an N^{th} process gas outlet over an N^{th} substrate at an N^{th} station.

Continuing, at 810, method 800 comprises flowing purge gas through purge holes formed through one or more shrouds of a purge plate. As described above, the shroud comprises a structure that extends from a chamber-facing surface of the purge plate. The shroud may be arranged at least partially around a perimeter of a cutout accommodating the first process gas outlet or the second process gas outlet. In some examples, a plurality of cutouts may have shrouds. The use of a purge plate including a shroud may help prevent crosstalk between stations of the processing chamber by directing gases away from other stations and towards an exhaust port. In some examples, the purge plate comprises a unitary body that comprises the shroud. In some examples, at 812, method 800 comprises flowing purge gas through purge holes formed in a chamber-facing surface of the purge plate. In some examples, at 814, method 800 further comprises flowing purge gas out the processing chamber via an exhaust system.

In some examples, method 800 further comprises, at 816, transferring the first substrate to the second station and transferring the second substrate to a third station. In some examples, at 818, method 800 comprises transferring the substrates via a transfer ring and an indexing plate. In other examples, substrates may be transferred by direct handling, rather than via a transfer ring.

By processing substrates within a processing chamber comprising a purge plate that includes a shroud, the examples disclosed herein may help to lessen a risk of crosstalk between stations. Thus, the examples disclosed may facilitate processing of multiple substrates within a single processing chamber using different chemistries at different stations.

In addition to crosstalk, other issues can arise in a deposition system. As described above, chemical vapor deposition and atomic layer deposition processes are generally performed in a processing chamber under a controlled gaseous environment. Processing chemicals may be introduced into the processing chamber through a processing chemical outlet. For example, processing chemicals may be introduced through a showerhead disposed above the substrate. The substrate may be supported by a pedestal system comprising a pedestal and pedestal support. During processing, the substrate may rest on the top surface of the pedestal. In some examples, a pedestal may comprise a substrate heater configured to heat the substrate. The pedestal support may comprise a column, for example, configured to raise and lower the pedestal and substrate. Further, lift pins extending through lift pin holes in the pedestal may help support the substrate during transfer. For example, when the pedestal is lowered, the lift pins may support the substrate above the pedestal to facilitate transfer of the substrate using a robot.

Processing conditions may involve application of a partial vacuum inside the processing chamber. This may cause a degree of bowing in a chamber top plate, such as a purge plate. The bowing may result in a slight tilting of a surface of the processing chemical outlet, such as a showerhead, relative to a surface of the pedestal. To compensate for this effect, the pedestal can be tilted such that the substrate and processing chemical outlet are approximately parallel when the processing chamber is at a processing pressure.

In addition to low pressure, processing conditions also may involve high temperatures (e.g., >300° C.) and presence of processing chemicals. Such processing conditions may cause wear to structures inside the processing chamber. For example, a substrate heater may heat a pedestal support and other structures by radiation, conduction, and/or convection of processing chemicals. Further, deposition of processing chemicals may occur on pedestal system surfaces such as the backside of the pedestal, pedestal support, and within lift pin holes. Chemical deposition may be facilitated by elevated temperatures on such surfaces. Over time, high temperatures and/or buildup from chemical deposition may lead to stress on the pedestal support. Maintenance to correct such issues may be labor intensive and/or costly.

One option to protect a pedestal system from temperature and/or processing chemicals is to position a shield around the pedestal support and pedestal. A purge gas then can be flowed through a space between the pedestal support and the shield to reduce chemical deposition on the pedestal support. However, the use of such shields may pose challenges. For example, some processing conditions may comprise temperatures in a range of 400° C. to 500° C. Under such conditions, shield temperatures may be greater than 300° C. As such, it may not be feasible to use metal alloys (e.g., aluminum 6061) that may experience outgassing and warping above 300° C. Ceramic shields also can be used to avoid warping and outgassing. However, ceramics may incur additional cost. It can also be difficult to adjust a pedestal shield to match a tilt of a pedestal. Additionally, the use of a shield may complicate lift pin adjustment, as lift pins and shims may not be accessible without removal of the shield.

Accordingly, examples are disclosed that relate to a pedestal shield system for use in a processing chamber of a substrate processing tool. As described in more detail below, the examples disclosed may help to protect a pedestal system from processing conditions such as high temperature and/or chemical deposition.

Briefly, a pedestal shield system comprises a side shield, a bottom shield, and a radiation shield. The bottom shield is disposed below a pedestal on a bottom surface of the processing chamber. The side shield is disposed around the pedestal support and is supported by the bottom shield. The bottom shield comprises adjustors configured to adjust side shield height and/or side shield tilt. The side shield at least partially encloses a space under the pedestal which may be purged using a purge gas. As such, the side shield may help protect a pedestal system and lift pins from processing conditions. The radiation shield comprises foot pads that extend through openings in the bottom shield to contact another structure in the processing chamber for heat transfer. The radiation shield is configured to absorb heat radiated from the pedestal system and conduct the heat for removal from the processing chamber. For example, heat may be transferred from the foot pads to a bottom surface of the processing chamber.

A pedestal shield system according to the present disclosure thus may help to mitigate the detrimental effects of processing conditions on a pedestal system. The disclosed example pedestal shield systems may conduct heat from the pedestal system with sufficient efficiency to allow the use of less expensive aluminum alloys instead of ceramics. For example, when a substrate heater is heated to ˜500° C., a side shield temperature may remain below 300° C. This may avoid outgassing and/or warping that can occur in some aluminum alloys at higher temperatures.

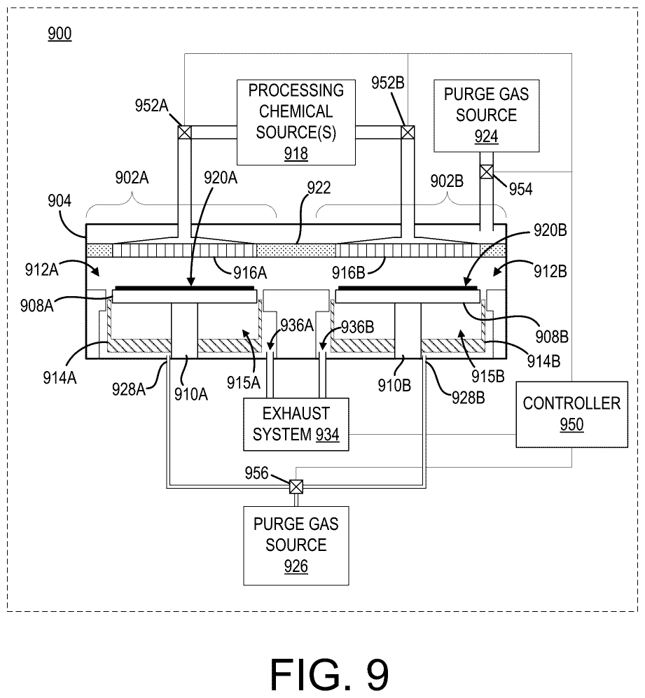

Prior to discussing these examples in detail, FIG. 9 schematically shows an example processing tool 900. Processing tool 900 is configured as a multi-station processing tool configured to process multiple substrates in parallel. FIG. 9 illustrates a first processing station 902A and a second processing station 902B within a processing chamber 904. Each of first processing station 902A and second processing station 902B is configured to expose a substrate to one or more processing chemicals. Processing tool 900 further may comprise additional stations not shown in FIG. 9. In other examples, a processing tool may comprise a single processing station. In some examples, processing tool 900 comprises a chemical vapor deposition tool configured to perform chemical vapor deposition. In some examples, processing tool 900 alternatively or additionally may comprise an atomic layer deposition tool configured to perform atomic layer deposition.

First processing station 902A comprises a first pedestal 908A and a first pedestal support 910A positioned within a first well 912A of processing chamber 904. First processing station 902A further comprises a first pedestal shield system 914A disposed around first pedestal support 910A. First pedestal shield system 914A may at least partially enclose a first space 915A around first pedestal support 910A and under first pedestal 908A. Details of example pedestal shield systems suitable for use as first pedestal shield system 914A are described in more detail below.

First processing station 902A further comprises a first processing chemical outlet 916A in fluid connection with a processing chemical source(s) 918. Processing chemical source(s) 918 may be configured to provide a processing chemical to first processing chemical outlet 916A. In some examples, processing chemical source(s) 918 may be configured to provide a mixture of processing chemicals.

First pedestal 908A supports a first substrate 920A during processing. First pedestal support 910A is configured to raise and lower first pedestal 908A, for example, to adjust the gap between first pedestal 908A and first processing chemical outlet 916A. First pedestal support 910A further may be configured to adjust a tilt of first pedestal 908A.

First pedestal 908A may comprise lift pin holes through which lift pins (omitted from FIG. 9 for clarity) can extend. Lowering first pedestal 908A may cause lift pins to extend through the lift pins holes to support first substrate 920A. Raising first pedestal 908A may cause the lift pins to retract.

Similarly, second processing station 902B comprises a second pedestal 908B and a second pedestal support 910B positioned within a second well 912B. Second pedestal support 910B is configured to raise and lower second pedestal 908B. Second pedestal support 910B also may be configured to adjust a tilt of second pedestal 908B. Second processing station 902B further comprises a second pedestal shield system 914B disposed around second pedestal support 910B. Second pedestal shield system 914B may at least partially enclose a second space 915B around second pedestal support 910B and under second pedestal 908B. Details of example pedestal shield systems suitable for use as second pedestal shield system 914B are described in more detail below.

Second processing station 902B further comprises a second processing chemical outlet 916B in fluid connection with processing chemical source(s) 918. Processing chemical source(s) 918 may be configured to provide one or more processing chemicals to second processing chemical outlet 916B. In some examples, a different processing chemical source may be in fluid connection with second processing chemical outlet 916B. This may allow different processing chemicals to be introduced into first processing station 902A and second processing station 902B.

Processing chamber 904 further comprises a top plate 922, first processing chemical outlet 916A, and second processing chemical outlet 916B. Processing tool 900 further comprises a purge gas source 924 comprising a purge gas that can be directed into processing chamber 904 through purge gas holes formed in top plate 922. Processing tool 900 further comprises a purge gas source 926 comprising a purge gas that can be directed into first space 915A through purge gas outlet 928A, and into second space 915B through purge gas outlet 928B. The purge gas may flow into a space through a gap between a pedestal shield system and a pedestal support. In some examples, a same purge gas source may be used for purge gas source 924 and purge gas source 926.

As described above, reduced pressure within processing chamber 904 may cause a degree of bowing of top plate 922. This can lead to a degree of tilting of first processing chemical outlet 916A and/or tilting of second processing chemical outlet 916B when processing chamber 904 is under vacuum. Thus, as described above, first pedestal support 910A may be configured to allow adjustment of a tilt angle of first pedestal 908A. This may allow first pedestal 908A to be adjusted to be suitably parallel to first processing chemical outlet 916A when processing chamber 904 is under vacuum. Likewise, a tilt of second pedestal support 910B may be adjusted such that second substrate 920B is suitably parallel to second processing chemical outlet 916B.

Processing chamber 904 may be evacuated by an exhaust system 934 comprising one or more exhaust ports 936A-B. In the depicted example, first processing station 902A comprises a first exhaust port 936A. Similarly, second processing station 902B comprises a second exhaust port 936B.

Processing tool 900 may further comprise other components not depicted in FIG. 9. For example, processing tool 900 may comprise a substrate transfer system configured to transfer substrates between first processing station 902A and second processing station 902B.

Processing tool 900 further comprises a controller 950 configured to control processing tool 900 to perform process cycles. For example, controller 950 is controllably connected to valves 952A, 952B, 954, and 956 to control processing chemical flows and purge gas flows during and between process cycles. Controller 950 is also controllably connected to exhaust system 934. Controller 950 may control valves 952A, 952B, 954, 956 and exhaust system 934 to control pressure and gas composition inside processing chamber 904. Controller 950 also may control first pedestal support 910A and second pedestal support 910B to raise, lower, and/or tilt first pedestal 908A and second pedestal 908B. Controller 950 further may control one or more heaters heat first substrate 920A and/or second substrate 920B. Controller 950 additionally may control other components not shown in FIG. 9, such as gas line heaters, liquid cooling elements, substrate transfer robots, load locks, and/or any other suitable components.

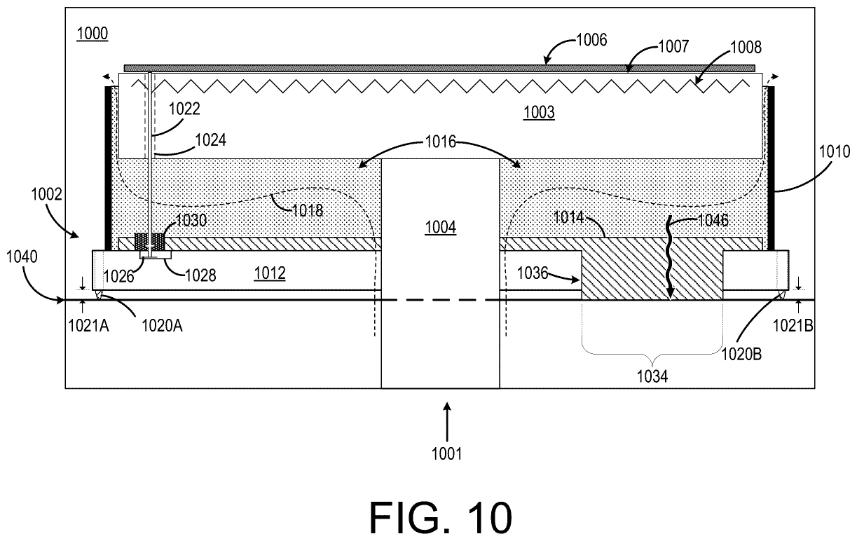

FIG. 10 schematically shows a cross-sectional side view of an example processing chamber 1000. Processing chamber 1000 comprises a pedestal system 1001 and a pedestal shield system 1002. Processing chamber 904 is an example of processing chamber 1000. Pedestal system 1001 comprises a pedestal 1003 supported by a pedestal support 1004. Pedestal support 1004 is configured to raise and lower pedestal 1003. Pedestal support 1004 is further configured to adjust a tilt angle of pedestal 1003 relative to a processing chemical outlet, as described below.

Pedestal 1003 is configured to support a substrate 1006 on a pedestal surface 1007. Pedestal 1003 comprises a substrate heater 1008 configured to heat substrate 1006. In some examples, substrate heater 1008 is configured to heat to a temperature within a range of 350° C. to 550° C. In other examples, a substrate heater may be omitted.

Processing chamber 1000 further comprises a pedestal shield system 1002 configured to at least partially protect pedestal system 1001 from processing conditions within processing chamber 1000. Pedestal shield system 1002 comprises a side shield 1010, a bottom shield 1012, and a radiation shield 1014.

Side shield 1010 is disposed around pedestal support 1004 and is supported by bottom shield 1012. Side shield 1010 may help protect pedestal system 1001 from processing conditions. For example, side shield 1010 at least partially encloses a space 1016 below pedestal 1003 through which a purge gas may be flowed (indicated by flow arrow 1018 and similar arrows). As such, side shield 1010 may inhibit chemical deposition on pedestal 1003 and pedestal support 1004 by at least partially blocking flow of processing chemicals into space 1016. In various examples, side shield 1010 and bottom shield 1012 may be integrated or may be separate. In some examples, side shield 1010 comprises aluminum and/or an aluminum alloy.

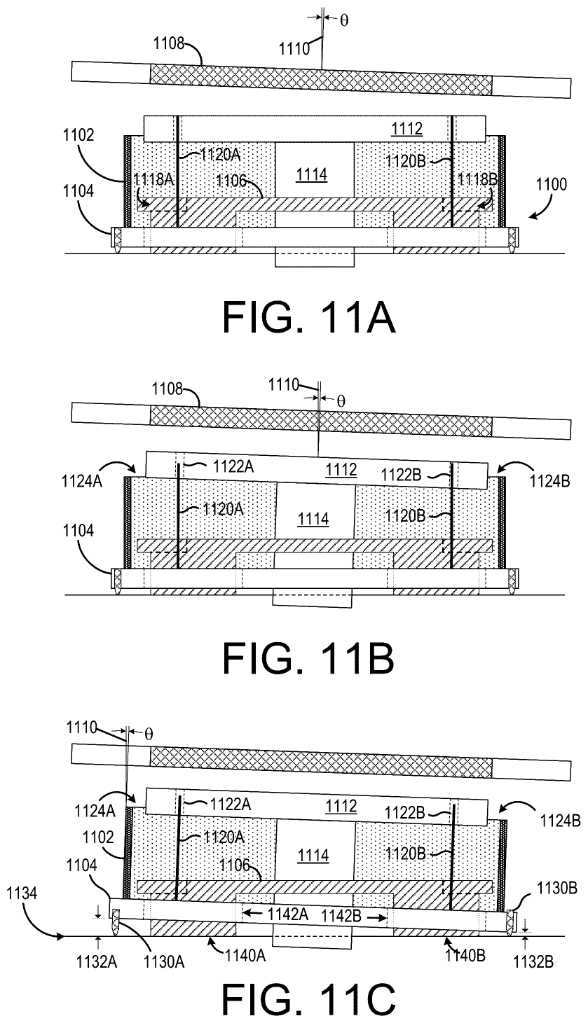

Bottom shield 1012 comprises a plurality of adjustors. Two adjustors, adjustor 1020A and adjustor 1020B, are shown. Each adjustor is capable of adjusting a height of a location of the bottom shield relative to an underlying surface. For example, adjustor 1020A is capable of adjusting height 1021A and adjustor 1020B is capable of adjusting height 1021B. As discussed in more detail below with regard to FIGS. 11A-11C, the plurality of adjustors are configured to adjust one or more of side shield height, side shield tilt, lift pin height, and lift pin angle. Example adjustors that may be suitable for use as each adjustor in bottom shield 1012 include a screw, a cam, a rack and pinion gear, a lever, a piston, a wedge, and combinations of two or more thereof. In some examples, a bottom shield may comprise three adjustors. In other examples, any other suitable number of adjustors may be used. Adjustors 1020A and 1020B may be accessed from corresponding openings in an upper side of bottom shield 1012.

Bottom shield 1012 is further configured to support a plurality of lift pins, such as lift pin 1022. Lift pin 1022 extends through a lift pin hole 1024 within pedestal 1003 such that an upper end of lift pin 1022 can support substrate 1006. Lift pin 1022 may support substrate 1006 when the upper end of lift pin 1022 is elevated above a height of pedestal surface 1007. For example, pedestal 1003 may be raised such that lift pin 1022 retracts through lift pin hole 1024 and substrate 1006 is supported by pedestal 1003. Likewise, pedestal 1003 may be lowered such that substrate 1006 is supported by the plurality of lift pins. In some examples, the plurality of lift pins comprises three lift pins, including lift pin 1022. In other examples, any other suitable number of lift pins may be used. Lift pins may comprise any suitable material. Examples include as aluminum, sapphire, corrosion-resistant steel, and ceramic.

In FIG. 10, a lower end of lift pin 1022 is supported by a shim 1026 disposed within a recess 1028 of bottom shield 1012. Shim 1026 may be removable such that a user can exchange shim 1026 for another shim of a different thickness. Shims may comprise any suitable material, such as aluminum, sapphire, corrosion-resistant steel, or ceramic. In other examples, shims and/or recesses may be optional. In other examples, such shims may be omitted.

As discussed above, pedestal 1003 may be raised and lowered. To avoid lift pin 1022 being pulled upwards when the pedestal is raised, lift pin 1022 may comprise a weight 1030. In other examples, weight 1030 may be omitted.

Bottom shield 1012 further comprises one or more openings to accommodate foot pads of radiation shield 1014. For example, opening 1034 is configured to accommodate foot pad 1036. In some examples, a bottom shield may have from three to six openings. In other examples, a bottom shield may comprise a number of openings outside of this range.

Bottom shield 1012 may contact a bottom surface 1040 of processing chamber 1000 at relatively few points, such as three points. As such, there may be little heat conduction from bottom shield 1012 to an underlying surface. Thus, radiation shield 1014 is configured to absorb heat radiated from the pedestal system 1001, and conduct the heat for removal from processing chamber 1000. Radiation shield 1014 comprises one or more foot pads, including foot pad 1036, to transfer heat to another structure in a processing chamber. The one or more foot pads extend through openings in bottom shield 1012. For example, foot pad 1036 extends through opening 1034 and is in thermal communication with bottom surface 1040. As depicted by arrow 1046, foot pad 1036 may conduct heat to bottom surface 1040 to remove the heat from pedestal system 1001. In some examples, bottom surface 1040 is actively cooled, e.g., by flowing a liquid through a channel beneath bottom surface 1040. In some examples, a foot pad may conduct heat to another structure within processing chamber 1000, such as a heat sink that is separate from a bottom surface of a process chamber.

As mentioned above, a pedestal shield system according to the present disclosure may be configured to facilitate adjustment of a side shield position and/or lift pin position relative to a position of a pedestal. FIGS. 11A-11C schematically show adjustment of an example shield system 1100 within a processing chamber of a processing tool. Shield system 1100 comprises a side shield 1102, a bottom shield 1104 supporting the side shield, and a radiation shield 1106. The processing chamber comprises a processing chemical outlet 1108 that is tilted to a tilt angle 1110, represented as angle θ. Such tilting may arise, for example, from bowing of top plate 922 (e.g., a processing chamber top plate) when a processing chamber is under reduced pressure. The depicted magnitude of the tilt of processing chemical outlet 1108 is exaggerated for clarity.

The processing tool comprises a pedestal 1112 supported by a pedestal support 1114. The processing tool further comprises lift pin 1120A and lift pin 1120B that extend through corresponding lift pin hole 1122A and lift pin hole 1122B of pedestal 1112.

Due to the tilt of processing chemical outlet 1108, pedestal 1112 and processing chemical outlet 1108 are not parallel, which may affect film deposition.

Thus, as described above, a pedestal tilt may be adjusted to align with a processing chemical outlet tilt. As depicted in FIG. 11B, pedestal support 1114 and pedestal 1112 are adjusted to tilt angle 1110. As a result, pedestal 1112 is approximately parallel to processing chemical outlet 1108.

Upon tilting pedestal 1112, lift pin 1120A and lift pin 1120B are misaligned with pedestal 1112. For example, as shown in FIG. 11B, the upper ends of lift pins 1120A, 1120B are misaligned with the surface of pedestal 1112. As such, lift pins 1120A, 1120B may become stuck and/or break during lowering of pedestal 1112.

Also, side shield 1102 is misaligned with pedestal 1112. As a result, gap 1124A may become wider and allow processing chemicals to enter the space below pedestal 1112. Additionally, gap 1124B may become narrower. This may interrupt a flow of purge gas. As such, adjusting a tilt of a pedestal without adjusting a side shield may expose the pedestal system to processing conditions.

Accordingly, the position of bottom shield 1104 is adjusted using one or more adjustors of bottom shield 1104. Example adjustors are shown at 1130A and 1130B. As shown in FIG. 11C, adjustor 1130A is adjusted to increase a gap 1132A between a first location of bottom shield 1104 and a bottom surface 1134 of the processing chamber. Additionally, adjustor 1130B is adjusted to decrease a gap 1132B between a second location of bottom shield 1104 and bottom surface 1134. Each adjustor 1130A, 1130B may use any suitable adjustment mechanism. Examples include a screw, a cam, a rack and pinion gear, a lever, a piston, a wedge, or any combination of any two or more thereof. While two adjustors are depicted in FIGS. 11A-11C, bottom shield 1104 may comprise any suitable number of adjustors. For example, by using three adjustors, bottom shield 1104 may function as a tripod whereby the three adjustors can independently be adjusted to control a height and a tilt of the tripod. As a result of the adjustment, side shield 1102 is tilted to an angle that is approximately equal to tilt angle 1110. In some examples, the position of shield system 1100 may also be adjusted in an X-Y plane on bottom surface 1134, which may help achieve similarity between gap 1124A and gap 1124B.

The positions of lift pins 1120A, 1120B also are adjusted by adjustor 1130A and adjustor 1130B. As depicted in FIG. 11C, increasing gap 1132A by adjusting adjustor 1130A while also decreasing gap 1132B by adjusting adjustor 1130B has the effect of raising a lift pin height of lift pin 1120A, lowering a lift pin height of lift pin 1120B, and adjusting an angle of both lift pins. In the example depicted in FIGS. 11A-11C, lift pin height represents a distance from bottom surface 1134 to an upper end of a lift pin. Adjustment of the lift pin angle may help align lift pin 1120A with lift pin hole 1122A and align lift pin 1120B with lift pin hole 1122B. As such, this may help avoid the lift pins being damaged or stuck during pedestal raising/lowering.

Additionally, lift pin planarity may be adjusted relative to the surface of pedestal 1112 such that the upper ends of lift pins 1120A, 1120B are approximately planar with the surface of pedestal 1112. Here, lift pin planarity represents a degree of planarity between a plane defined by upper ends of three or more lift pins, including lift pin 1120A and lift pin 1120B, and the surface of pedestal 1112. As depicted in FIG. 11C, when pedestal 1112 is lowered, lift pins 1120A, 1120B may contact a substrate disposed on top of pedestal 1112 together.

Adjusting lift pin height and lift pin planarity by adjusting adjustors 1130A-B may be more convenient for a user compared to other methods such as adjustment of lift pin lengths or adjustment of shims. For example, it may be labor intensive to remove a shield to access shims and lift pins, adjust the shims and lift pins, and then replace the shield. In comparison, it may be relatively fast for a user to adjust adjustors 1130A-B, for example, by twisting a screw. In other examples, shims may be used to adjust a height of a lift pin independently of adjustors 1130A-B.

As shown in FIG. 11C, foot pads 1140A, 1140B of radiation shield 1106 maintain contact with bottom surface 1134 when bottom shield 1104 is adjusted. Foot pads 1140A, 1140B extend through openings 1142A, 1142B in bottom shield 1104. As such, radiation shield 1106 does not tilt with bottom shield 1104. Thus, radiation shield 1106 can conduct heat through foot pads 1140A, 1140B for removal of the heat from the processing chamber when bottom shield 1104 is adjusted.

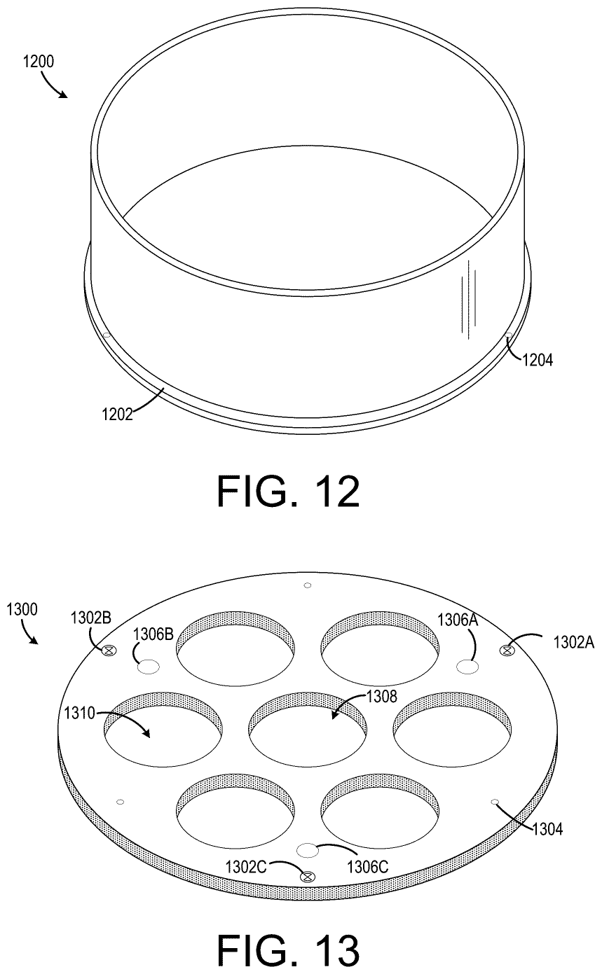

FIG. 12 schematically shows an example side shield 1200 configured for use in a pedestal shield system. Side shield 1200 is an example of side shield 1010 of FIG. 10 or side shield 1102 of FIGS. 11A-11C. Side shield 1200 may be disposed around a pedestal support of a pedestal system to help protect the pedestal system from processing conditions. Side shield 1200 may be supported by a bottom shield. In some examples, a side shield may be integrated with a bottom shield.

Side shield 1200 comprises an approximately cylindrical shape. In other examples a side shield may comprise any other suitable shape. Side shield 1200 comprises a flange 1202 with fastener holes 1204. Flange 1202 may help transfer heat from side shield 1200 to a bottom shield supporting side shield 1200. Fasteners, such as screws, may be inserted through fastener holes 1204 to help secure side shield 1200 to a bottom shield.

In some examples, side shield 1200 comprises aluminum and/or an aluminum alloy. As discussed above, processing conditions comprising temperatures above 300° C. may lead to outgassing of metal alloys (e.g., aluminum 6061) which may deform, damage, and/or weaken the metal alloy. However, the examples disclosed herein may provide for relatively lower temperatures of a side shield under processing conditions. For example, in one experiment, a substrate heater was heated to 500° C., and a side shield temperature was measured to be below 225° C. As such, the examples disclosed herein may provide for the use of side shields comprising metal alloys (e.g., aluminum alloys such as aluminum 6061), which may be less expensive than ceramic. In other examples, side shield 1200 may comprise any other suitable material. Examples include corrosion-resistant steel or ceramic.

FIG. 13 schematically shows an example bottom shield 1300 configured for use in a pedestal shield system. Bottom shield 1300 is an example of bottom shield 1012 of FIG. 10 or bottom shield 1104 of FIGS. 11A-11C. Bottom shield 1300 is configured to support a side shield, such as side shield 1010, side shield 1102, or side shield 1200. As depicted in FIG. 13, bottom shield 1300 comprises three adjustors 1302A-C. In other examples, a bottom shield may comprise any other suitable number of adjustors. Example adjustors may include a screw, a cam, a rack and pinion gear, a lever, a piston, a wedge, or any combination of two or more of these structures. In some examples, an adjustor may comprise a locking mechanism to lock the adjustor and prevent movement. For example, an adjustor may comprise an adjustment screw and locking screw. In such an example, the locking screw may partially cover or otherwise block the adjustment screw when in a locked position. The adjustment screw can be adjusted when the locking screw is in an unlocked position, and not adjusted when the locking screw is in a locked position.

Bottom shield 1300 further comprises fastener holes 1304 that can be aligned with corresponding fastener holes of a side shield to facilitate an attachment of the side shield to bottom shield 1300. Examples include fastener holes 1204 of side shield 1200. For example, a screw threaded through fastener holes 1204 and fastener holes 1304 may be used to secure side shield 1200 to bottom shield 1300. In other examples, any suitable fastener may be used. Examples include clamps and bolts. In further examples, a fastener may be omitted. For example, a bottom shield may comprise a groove configured to accommodate a side shield and hold the side shield by friction.

Bottom shield 1300 further comprises a plurality of features 1306A-C configured to support a corresponding plurality of lift pins. In some examples, features 1306A-C may be configured to prevent a lift pin from shifting. For example, features 1306A-C may be recesses in which lift pins may rest. In some examples, features 1306A-C may be configured to accommodate a weight and/or lift pin assembly. For example, a weight may at least partially rest within a recess. Further, in some examples, a shim may be placed in a feature such that the shim is disposed between a lift pin and bottom shield 1300. Referring back to FIG. 10, recess 1028 is an example of a feature that can accommodate a shim to support a lift pin.

As discussed above, adjustors 1302A-C may be configured to adjust one or more of a lift pin height, a lift pin angle, a side shield height, and a side shield tilt. Adjustors 1302A-C may be adjusted together to raise and lower bottom shield 1300. Further, by tilting bottom shield 1300, adjustors 1302A-C can be used to adjust a side shield tilt and a lift pin angle relative to a pedestal.

Bottom shield 1300 further comprises a plurality of openings including opening 1308 and opening 1310. Opening 1308 is located near the center of bottom shield 1300 and is configured to accommodate a pedestal support of a pedestal system. Opening 1308 also may be configured to allow a purge gas to flow around the pedestal support through opening 1308. Opening 1310 is located near the edge of bottom shield 1300 and is configured to accommodate a foot pad of a radiation shield. Bottom shield 1300 comprises six openings configured to accommodate foot pads. However, in other examples, a bottom shield may comprise any suitable number of openings to accommodate any suitable number of foot pads. Openings may comprise any suitable shape and size. Further, an opening may be configured to accommodate two or more foot pads in some examples.

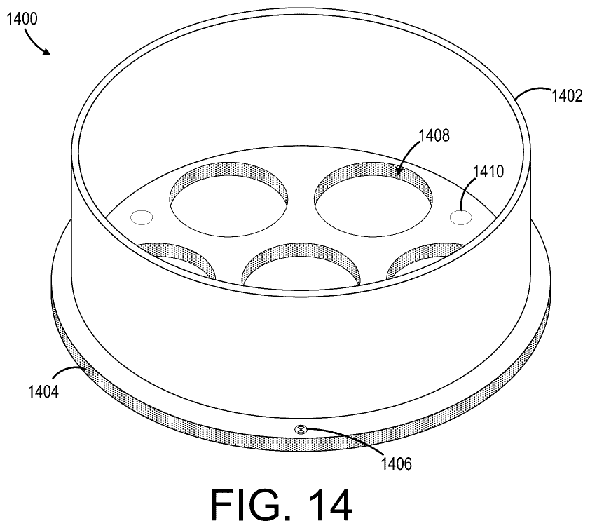

As described above, a side shield and a bottom shield may be integrated in some examples. FIG. 14 shows an example integrated bottom and side shield 1400 comprising a side shield portion 1402 and a bottom shield portion 1404. Integrated bottom and side shield 1400 further comprises one or more adjustors, including adjustor 1406, configured to adjust one or more of a side shield tilt and a side shield height. Integrated bottom and side shield 1400 further comprises one or more openings, including opening 1408, configured to accommodate a foot pad of a radiation shield. Integrated bottom and side shield 1400 also comprises one or more features, including feature 1410, configured to accommodate one or more lift pins. Side shield portion 1402 and bottom shield portion 1404 may be joined in any suitable manner, e.g., welding. In some examples, integrated bottom and side shield 1400 may be machined, cast or otherwise formed as a single part. Further, in some examples, integrated bottom and side shield 1400 comprises aluminum and/or an aluminum alloy.

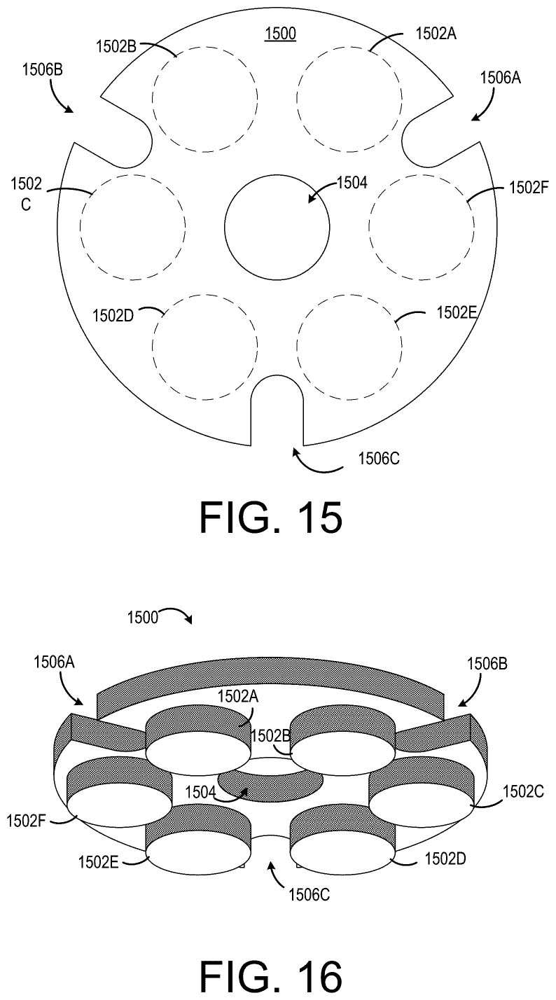

FIG. 15 shows a schematic view of an example radiation shield 1500 from a top view. Radiation shield 1500 is an example of radiation shield 1014 of FIG. 10 or radiation shield 1106 of FIGS. 11A-11C. Radiation shield 1500 comprises six foot pads 1502A-F, indicated by dashed lines. FIG. 16 shows a perspective view of radiation shield 1500 that shows the bottom of radiation shield 1500. As seen in FIG. 16, the foot pads 1502A-F of radiation shield 1500 extend downwardly. When used with a bottom shield, the foot pads 1502A-F extend downwardly through openings in the bottom shield, such as through opening 1310 of bottom shield 1300. Radiation shield 1500 is configured to absorb heat from a pedestal system. Further, the foot pads 1502A-F are configured to conduct the heat for removal of the heat from the processing chamber. In some examples, the foot pads 1502A-F may comprise a material comprising relatively high thermal conductivity, such as copper. In other examples, any other suitable material may be used. While the example depicted in FIGS. 15-16 comprises six foot pads, a radiation shield may comprise any suitable number of foot pads. Further, foot pads may comprise any suitable shape.

Radiation shield 1500 further comprises an opening 1504 configured to accommodate a pedestal support of a pedestal system. Opening 1504 also may be configured to allow purge gas to flow around a pedestal support through opening 1504. Radiation shield 1500 further comprises a plurality of cutouts 1506A-C configured to accommodate one or more lift pins. For example, cutout 1506A may accommodate a first lift pin to extend through radiation shield 1500 to be supported by a bottom shield (e.g., at feature 1306A of bottom shield 1300). Likewise, cutout 1506B may accommodate a second lift pin. Cutout 1506C may accommodate a third lift pin.

As mentioned above, pedestal shield system may be adjusted to achieve and maintain suitable alignment with a pedestal system. For example, a pedestal shield system may be adjusted during manufacturing or maintenance of a processing tool.

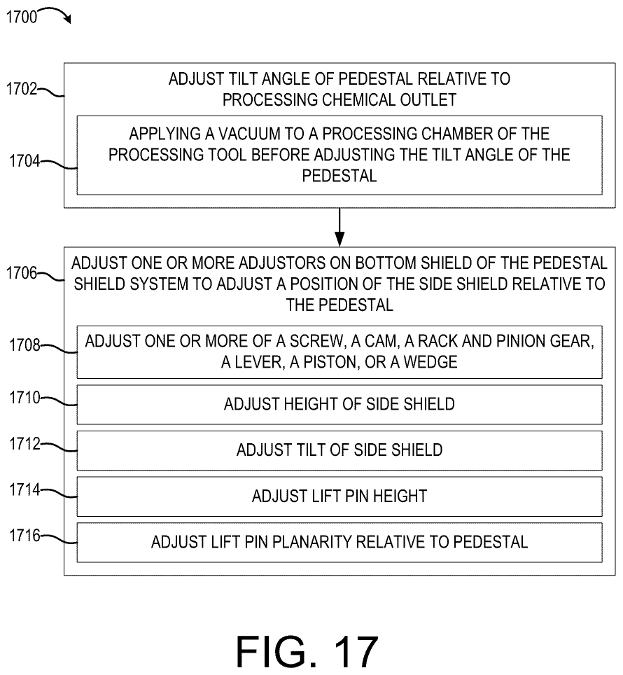

FIG. 17 shows an example method 1700 of adjusting a pedestal shield system. The pedestal system of the substrate processing tool comprises a pedestal and a pedestal support. The pedestal shield system of the substrate processing tool comprises a side shield, a bottom shield, and a radiation shield. At 1702, method 1700 comprises adjusting a tilt angle of the pedestal relative to the processing chemical outlet. As described above, application of a vacuum may cause bowing in a top plate of the processing chamber which leads to tilt of the processing chemical outlet. Thus, adjusting the tilt angle of the pedestal at 1704 may comprise applying a vacuum to a processing chamber of the processing tool before adjusting the tilt angle of the pedestal.

Method 1700 further comprises, at 1706, adjusting one or more adjustors on the bottom shield of the pedestal shield system to adjust a position of the side shield relative to the pedestal. In some examples, at 1708, adjusting the one or more adjustors comprises adjusting one or more of a screw, a cam, a rack and pinion gear, a lever, a piston, or a wedge. In some examples, at 1710, adjusting the one or more adjustors may comprise adjusting a height of the side shield. In some examples, at 1712, adjusting the one or more adjustors may comprise adjusting a tilt of the side shield. Further, in some examples, at 1714, adjusting the one or more adjustors may comprise adjusting a lift pin height of one or more lift pins supported by the bottom shield. Also, in some examples, at 1716, adjusting the one or more adjustors may comprise adjusting a lift pin planarity relative to a surface of the pedestal.

It will be understood that the disclosed examples of pedestal shield systems and purge plates can be used in a same processing station of a processing tool in some examples. The disclosed example pedestal shield systems can help protect a pedestal from conditions such as high temperatures and processing gases. Further, the disclosed example purge plates can help prevent cross-talk between stations of a multi-station tool.

In some examples, the methods and processes described herein may be tied to a computing system of one or more computing devices. In particular, such methods and processes may be implemented as a computer-application program or service, an application-programming interface (API), a library, and/or other computer-program product.

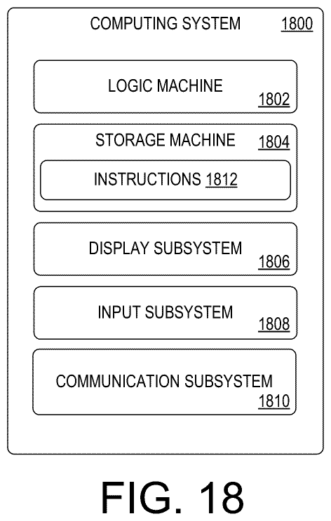

FIG. 18 schematically shows a non-limiting example of a computing system 1800 that can enact one or more of the methods and processes described above. Computing system 1800 is shown in simplified form. Computing system 1800 may take the form of one or more personal computers, workstations, computers integrated with wafer processing tools, and/or network accessible server computers.

Computing system 1800 includes a logic machine 1802 and a storage machine 1804. Computing system 1800 may optionally include a display subsystem 1806, input subsystem 1808, communication subsystem 1810, and/or other components not shown in FIG. 18. Controllers 150 and 950 are examples of computing system 1800.

Logic machine 1802 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1804 includes one or more physical devices configured to hold instructions 1812 executable by the logic machine to implement the methods and processes described herein. When such methods and processes are implemented, the state of storage machine 1804 may be transformed—e.g., to hold different data.

Storage machine 1804 may include removable and/or built-in devices. Storage machine 1804 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1804 may include volatile, nonvolatile, dynamic, static, read/write, read-only, random-access, sequential-access, location-addressable, file-addressable, and/or content-addressable devices.

It will be appreciated that storage machine 1804 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1802 and storage machine 1804 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1806 may be used to present a visual representation of data held by storage machine 1804. This visual representation may take the form of a graphical user interface (GUI). As the herein described methods and processes change the data held by the storage machine, and thus transform the state of the storage machine, the state of display subsystem 1806 may likewise be transformed to visually represent changes in the underlying data. Display subsystem 1806 may include one or more display devices utilizing virtually any type of technology. Such display devices may be combined with logic machine 1802 and/or storage machine 1804 in a shared enclosure, or such display devices may be peripheral display devices.

When included, input subsystem 1808 may comprise or interface with one or more user-input devices such as a keyboard, mouse, or touch screen. In some examples, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 1810 may be configured to communicatively couple computing system 1800 with one or more other computing devices. Communication subsystem 1810 may include wired and/or wireless communication devices compatible with one or more different communication protocols. As non-limiting examples, the communication subsystem may be configured for communication via a wireless telephone network, or a wired or wireless local- or wide-area network. In some examples, the communication subsystem may allow computing system 1800 to send and/or receive messages to and/or from other devices via a network such as the Internet.

It will be understood that the configurations and/or approaches described herein are exemplary in nature, and that these specific examples or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A processing tool comprising:
a processing chamber comprising
a plurality of stations, and
a purge plate comprising
a chamber-facing surface,
a plurality of cutouts configured to accommodate a process gas outlets of the plurality of stations,
a shroud arranged around at least a portion of a perimeter of a first cutout of the plurality of cutouts, the shroud extending away from the chamber-facing surface, and
a plurality of purge gas holes formed in the chamber-facing surface and the shroud.

2. The processing tool of claim 1, wherein the shroud is a first shroud, and further comprising a second shroud arranged at least partially around the perimeter of a second cutout of the plurality of cutouts.

3. The processing tool of claim 1, wherein the plurality of purge gas holes comprises a pattern, and wherein the pattern is interrupted at an edge of the shroud.

4. The processing tool of claim 1, wherein the shroud is configured to accommodate one or more tabs of a transfer ring.

5. The processing tool of claim 1, further comprising a pedestal located at a station of the plurality of stations, a pedestal support that supports the pedestal above a bottom surface of the processing chamber, and a pedestal shield system comprising:
a side shield disposed around the pedestal support,
a bottom shield that supports the side shield, the bottom shield comprising a plurality of adjustors configured to adjust one or more of a side shield tilt and a side shield height, the bottom shield further comprising one or more openings, and
a radiation shield configured to absorb heat radiated from the pedestal and transfer the heat for removal from the processing chamber, the radiation shield comprising one or more foot pads that extend through the one or more openings of the bottom shield.

6. The processing tool of claim 5, wherein the side shield is disposed around the pedestal, and further comprising a purge gas outlet to flow purge gas into a space at least partially enclosed by the side shield.

7. The processing tool of claim 5, further comprising a plurality of lift pins supported by the bottom shield, and wherein the plurality of adjustors of the bottom shield are further configured to adjust one or more of lift pin height and lift pin angle relative to pedestal angle, wherein the radiation shield comprises a plurality of cutouts configured to accommodate the plurality of lift pins.

8. A purge plate for a processing chamber in a processing tool, the purge plate comprising:
a chamber-facing surface;
a cutout configured to accommodate a corresponding process gas outlet of the processing tool;
a shroud arranged around at least a portion of a perimeter of the cutout, the shroud extending from the chamber-facing surface; and
a plurality of purge gas holes formed in the chamber-facing surface and the shroud.

9. The purge plate of claim 8, wherein the purge plate comprises a unitary body.

10. The purge plate of claim 8, wherein the purge plate is formed from aluminum.

11. The purge plate of claim 8, wherein the shroud is a first shroud, and further comprising a second shroud arranged around a second cutout.

12. The purge plate of claim 8, wherein the plurality of purge gas holes comprises a pattern, the pattern being interrupted at an edge of the shroud.

13. The purge plate of claim 8, wherein the shroud extends away from the chamber-facing surface a distance within a range of between 0.10 inches and 0.25 inches.

14. The purge plate of claim 8, further comprising a second, third, and fourth cutout.

15. The purge plate of claim 8, wherein the shroud comprises one or more notches configured to accommodate one or more tabs of a transfer ring.

16. The purge plate of claim 8, wherein the purge plate is configured for a deposition chamber of a chemical vapor deposition tool.

17. A method of processing a plurality of substrates within a processing chamber of a processing tool, the processing chamber comprising a plurality of stations and a corresponding plurality of process gas outlets, the processing chamber further comprising a purge plate, the purge plate comprising a plurality of cutouts each configured to accommodate a process gas outlet of the plurality of process gas outlets, the method comprising:
flowing a first precursor gas over a first substrate at a first station;
flowing a second precursor gas over a second substrate at a second station;
flowing a purge gas through purge holes formed through a chamber-facing surface of the purge plate; and
flowing the purge gas through purge holes formed through a shroud of the purge plate, the shroud arranged around at least a portion of a perimeter of a first cutout of the plurality of cutouts.

18. The method of claim 17, wherein the shroud is a first shroud, and further comprising flowing the purge gas through purge holes formed in a second shroud of the purge plate, the second shroud arranged at least partially around a portion of a second cutout of the plurality of cutouts.

19. The method of claim 17, wherein the method of processing the plurality of substrates further comprises an additional method, the additional method comprising:
performing a chemical vapor deposition process.

20. The method of claim 17, further comprising, after flowing the first precursor gas, transferring the first substrate to the second station, and after flowing the second precursor gas, transferring the second substrate to a third station.
